(19) United States
(12) Patent Application Publication
(10) Pub. No.: US 2006/0184848 A1
(43) Pub. Date: Aug. 17, 2006

(54) Semiconductor integrated circuit having test function and manufacturing method

(75) Inventors: Mitsuo Serizawa, Kodaira (JP); Kaname Yamasaki, Tokyo (JP); Masafumi Yamamoto, Ome (JP); Kazuo Kato, Tokyo (JP)

Correspondence Address: Stanley P. Fisher;Reed Smith LLP, Suite 1400, 3110 Fairview Park Drive, Falls Church, VA, 22042-4503, US

(73) Assignee: Renesas Technology Corp.

(21) Appl. No.: 11/335,606

(22) Filed: Jan. 20, 2006

(30) Foreign Application Priority Data
Nov. 30, 2005 (JP) 2005-345094
Jan. 28, 2005 (JP) 2005-020505

(51) Int. Cl. G01R 31/28

(52) U.S. Cl. 714/727

(57) ABSTRACT

The logic integrated circuit comprises a logic circuit having the predetermined logic functions, a read/write memory circuit, a test circuit for testing whether fail bit is included in the memory circuit or not, and a boundary latch circuit formed of a plurality of flip-flop circuits which are capable of latching signals between said logic circuit and said memory circuit and also forming a shift register. Moreover, the logic integrated circuit is further provided with a fail relief information generating circuit for storing test result to the boundary latch circuit during execution of the test with the test circuit and generating the fail relief information for relieving fail of said memory circuit based on the stored test result. The test circuit mounted on the logic integrated circuit can generate the information for relieving fail bit in parallel with the test of a built-in memory circuit and can also output the same information to external side and relieve the RAM within a chip.

### CROSS-REFERENCE TO RELATED APPLICATION

The present application claims priority from Japanese application No. 2005-345094 filed on Nov. 30, 2005, and Japanese patent application No. 2005-020505 filed on Jan. 28, 2005, the contents of which are hereby incorporated by reference into this application.

### BACKGROUND OF THE INVENTION

The present invention relates to a technology which may be suitably adapted for mounting of a test circuit of a RAM (Random Access Memory) and a test circuit of a logic circuit in a semiconductor integrated circuit (logical integrated circuit) comprising the RAM and the logic circuit and moreover relates to a technology for obtaining relief information in parallel with test of the RAM by the test circuit. The present invention is a technology which can be effectively adapted to a logic LSI such as a system LSI (Large Scale Integrated circuit) comprising, for example, a RAM and a CPU (Central Processing Unit).

In general, as a test simplifying design method in the logic LSI called a system LSI to which the RAM and CPU or the like are mounted, the scan-path system has widely been utilized. In this system, a shift register has been constituted by connecting in serial the flip-flop circuits provided in an internal logic circuit, the test data is inputted to this shift register, and state of logic is extracted to the external side of the chip for inspection with the shift register by operating the internal logic circuit. Moreover, in order to detecting existence or non-existence of fail bits of the built-in RAM, the technology for conducting test of RAM has also been proposed (for example, the patent document 1). In this technology, a latch circuit which can constitute the shift register is allocated at the interface between logic part and RAM and a BIST (Built-In Self Test) circuit including a circuit for generating a test pattern of RAM and a circuit for comparing a readout data with an expected value is also provided.

[Patent Document 1]

Japanese Unexamined Patent Publication No. Hei 8(1996)-262116

### SUMMARY OF THE INVENTION

It has been impossible, among the existing test circuits for built-in RAM, to find the test circuit which can generate the relief information and then output the same information to the external side of chip and simultaneously relieve, in addition, the RAM within the chip, in parallel with the simultaneous tests of various kinds of RAM.

An object of the present invention, therefore, is to provide a logic integrated circuit which can, in parallel with test of built-in RAM, generate information for relief of fail bits, and output the same information to external side of a chip or relieve simultaneously the RAM within the chip.

Another object of the present invention is to provide a logic integrated circuit mounting a test circuit which can generate information for relieving fail bits of a built-in RAM, while controlling increase in the scale of circuit.

The aforementioned and the other objects and novel characteristics of the present invention will become apparent from the description of this specification and the accompanying drawings thereof.

Of the inventions disclosed by the present application, the representative ones will next be summarized briefly.

According to one aspect of the present invention, a logic integrated circuit comprises a logic circuit having the predetermined logic function, a memory circuit which enables data write and read operations (built-in RAM), a test circuit for testing whether fail bits are included in the memory circuit or not, a boundary latch circuit which can latch signals between logic circuit and memory circuit and is formed of a plurality of flip-flop circuits capable of constituting a shift register, and a fail relieving information generating circuit, wherein the test circuit collects, during execution of the test, test result to the boundary latch circuit and the fail relieving information generating circuit generates fail relieving information to relieve fail of the memory circuit on the basis of the test result.

Here, the memory circuit is preferably provided with a reserve memory group (memory column or memory row) and a fail relieving circuit for replacing the main memory group into the reserve memory group in order to realize replacement of memory groups by supplying the information generated by the fail relieving information generating circuit to the fail relieving circuit.

According to the means described above, information for relieving fail bits is generated in parallel with test of the built-in memory circuit and this information can be outputted to the external side of a chip or the memory circuit can also be relieved within the chip. Therefore, manufacturing cost can be lowered by shortening the test period. In addition, since the boundary latch circuit stores test result of the test circuit and the fail relieving information generating circuit generates the fail relieving information to relieve fail of the memory circuit based on the stored test result, the information for relieving fail of fail bits of the memory circuit can be generated while increase in the scale of circuit is restrained. Further, the present invention can apply a plurality of read/write memory circuits for different number of read bits to a logic integrated circuit and can generate the fail relieving information in parallel in a plurality of memory circuits.

Moreover, the respective boundary latch circuits of a plurality of memory circuits are preferably capable of constituting a shift scan-path. Therefore, since test results of the test circuit can be centralized to a point through only one scan-path, the number of signal lines can be reduced in the logic integrated circuit provided with many built-in memory circuits. As a result, the space required for wiring can be reduced and thereby chip size can also be reduced.

It is moreover preferable that the fail relieving circuit is provided with a plurality of selectors which are provided between memory array of the built-in memory circuit and data input/output terminals and are selectively connected one data line of the adjacent memory column. Here, the selector is controlled to select the data line skipping over the memory column including a fail. Therefore, the test circuit can be realized, in which the fail relieving information can be generated by a more simplified logic circuit and the fail relieving information of the memory circuit can also be generated while increase in the scale of circuit is restrained.

According to another aspect of the present invention, a semiconductor integrated circuit comprises a logic circuit, a first scan path for logic circuit, and a second scan path for memory circuit, wherein a flip-flop on the first scan path for storing test result of logic circuit and a flip-flop on the second scan path for storing test result of memory circuit are used in common.

The means described above can realize reduction in chip size by reducing the scale of the circuit for testing a logic circuit and a memory circuit.

An advantage of the representative inventions, of the inventions disclosed by the present application, will be described briefly.

According to the present invention, a logic integrated circuit mounting a test circuit can be realized, in which information for relieving fail bits can be generated in parallel with test of the built-in RAM, this information can be outputted to the external side of a chip or the RAM can also be relieved within the chip, and the information for relieving fail bits of the built-in RAM can be generated while increase in the scale of circuit can be restrained.

### BRIEF DESCRIPTION OF THE DRAWINGS

FIG. 1 is a block diagram illustrating a schematic structure of a test circuit (so-called a BIST circuit) for testing a built-in RAM of the present invention.

FIG. 2 is a block diagram illustrating a more detail structure of a bridge circuit in the test circuit (BIST circuit) of FIG. 1

FIG. 3 is a block diagram illustrating more detail structures of a multi-fail circuit 152 and a sequential encoder 153 in a BISR circuit 150.

FIG. 4 is a timing chart illustrating timings of relief information generating operations in the BISR circuit of FIG. 3.

FIG. 5 is a block diagram illustrating a schematic structure of a relief circuit provided in the RAM.

FIG. 6 is a block diagram illustrating a schematic structure of the relief circuit provided in the RAM of IO column structure.

FIG. 7 is a block diagram illustrating an example of embodied structure of a column address determining circuit 151 of the BISR circuit 150.

FIG. 8 is a block diagram illustrating an example of structure of a system LSI as an example of a logic integrated circuit which is suitably comprising the BIST circuit of the embodiment of the present invention.

FIG. 9 is a timing chart illustrating scan-in and scan-out timings during test of a logic circuit and also illustrating contents of outputs of flip-flop FF4, selectors SEL4, and SEL22 in each mode.

FIG. 10 is a block diagram illustrating an embodied example of an interface circuit using a TAP illustrated in FIG. 2.

FIG. 11 is an explanatory diagram illustrating connecting conditions between a tester and a chip on wafer in the testing process of the semiconductor integrated circuit simultaneously comprising the RAM and the logic circuit of the present invention.

FIG. 12 is a flowchart illustrating sequence of the testing process and assembling process of the semiconductor integrated circuit simultaneously comprising the RAM and the logic circuit of the present invention.

### DETAILED DESCRIPTION OF THE PREFERRED EMBODIMENT

A preferred embodiment of the present invention will be described with reference to the accompanying drawings.

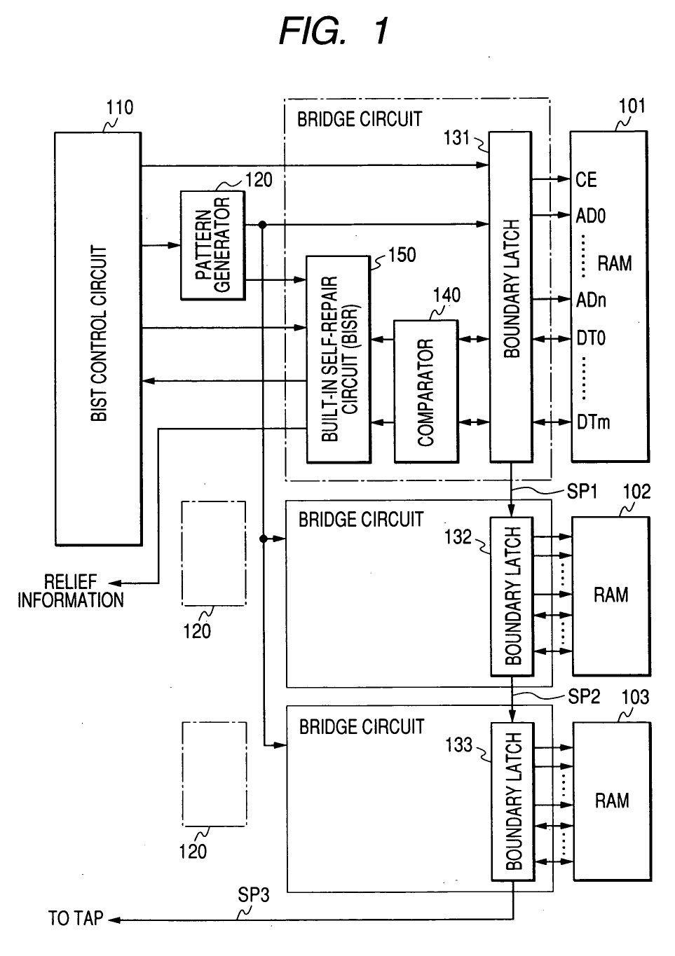

FIG. 1 illustrates a schematic diagram of a test circuit (so-called a BIST circuit) for testing a built-in RAM in the present invention. An LSI to which the test circuit of the embodiment of the present invention is applied is a logic LSI in which a plurality of RAMs, a CPU, and a logic circuit such as the peripheral circuit of the CPU are formed over one semiconductor chip. In FIG. 1, numerals 101 to 103 denote RAMs provided within the LSI. For the RAMs 101 to 103, the number of IO bits, namely the number of bits of the data to be inputted or outputted simultaneously may be identical or may be different.

Numeral 110 denotes a BIST control circuit for controlling an entire part of the test circuit; 120, a pattern generating circuit for generating address and data for testing the built-in RAM 101; 131 to 133, boundary latch circuits which are provided at the interface of the logic circuit not illustrated and the RAMs 101 to 103 and are formed of flip-flop circuits which are capable of forming a shift register. Moreover, numeral 140 denotes a comparing circuit for comparing the data read from the RAM 101 with the expected value generated by a pattern generating circuit 120; 150, a built-in self-repair circuit (BISR circuit) for generating fail column address and relief information on the basis of the comparison result by the comparing circuit 140 and the signal from the BIST control circuit.

In this embodiment, although not particularly restricted, the boundary latches 131 to 133 corresponding to the RAMs 101 to 103 are connected with scan-paths SP1, SP2 for memory test, and are constituted to shift the data stored in each boundary latch, send the same data to a TAP (test access port) via the scan-paths SP1 to SP3 and then output the data to the external side of a chip.

Application of this embodiment results in the advantage that one scan-path can be allocated along the edge portion of the chip and layout design of the scan-path can be made easily. Moreover, connection of the boundary latches of a plurality of RAMs can also provide such an advantage that, even in the LSI where TAP is not provided over the chip, the external terminals for outputting the test result can be reduced to only one terminal.

The pattern generating circuit 120 may be provided corresponding to respective RAMs 101 to 103 or may be provided as a common circuit for a plurality of RAMs. The BIST control circuit 110 is provided as a common circuit for all BIST circuits in the narrow sense as will be described later. In this embodiment, the circuit combining the boundary latch 131, comparing circuit 140 and BISR circuit 150 is called a bridge circuit. Moreover, the circuit combining the pattern generating circuit 120 and bridge circuit is called the BIST circuit of narrow sense, and the circuit combining the BIST circuit of narrow sense and the BIST control circuit 110 is called the BIST circuit of wider sense.

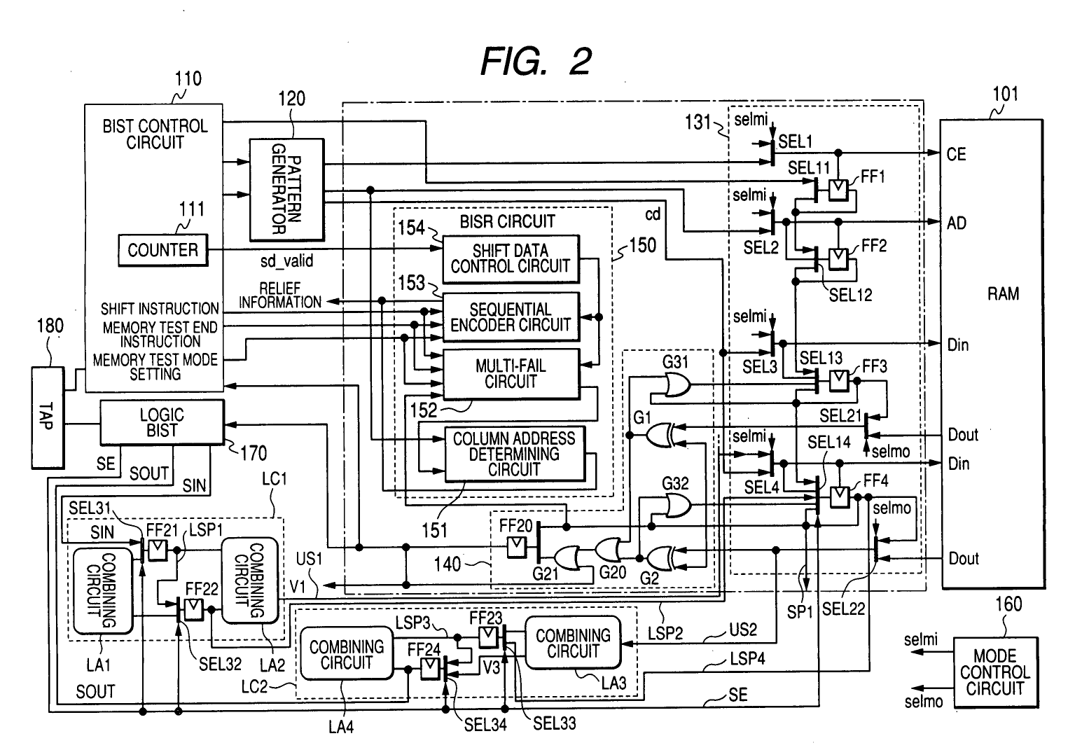

FIG. 2 illustrates a more detail structure of the bridge circuit. Since the structure of bridge circuit is basically identical even when the corresponding RAM is different, only the bridge circuit corresponding to the RAM 101 will be explained below.

As illustrated in FIG. 2, the boundary latch 131 comprises flip-flops FF1, FF2, FF3, . . . which are capable of forming a shift register, selectors SEL1, SEL2, SEL3, . . . for selecting any of the signal from a logic circuit LC1 . . . or the test pattern signal generated by the pattern generating circuit 120 and for sending the selected signal to the RAM 101 or to the flip-flops FF1, FF2, FF3, . . . which are capable of forming the shift register, selectors SEL1, SEL12, SEL13 . . . for selecting the scan-path or the like for the self loop to return outputs of the FF1, FF2, FF3, . . . to the own input or to the shift register, and selectors SEL21, SEL22, . . . , etc.

The selectors SEL21, SEL22, . . . are provided only to the point corresponding to the data signal Dout. Moreover, since it is difficult to illustrate all signal lines and circuits in FIG. 2 because of the convenience of illustration, the chip enable signal CE as presentative of the control signals inputted to the RAM 101, only one address signal AD, and only two data signals are illustrated in FIG. 2 and other signals are not illustrated. In the case where the storage capacity of RAM 101 is 2ⁿ words and the number of IO bits is 32 bits, the n address signals and 32 data signals are provided and the flip-flops FF2, FF3, FF4, . . . , selectors SEL12, SEL13, SEL14, . . . and SEL21, SEL22, . . . are provided respectively as much as the number corresponding to the number of signals.

The selectors SEL21, SEL22 . . . . . . . are controlled to select outputs of the FF3, FF4, . . . for storing test pattern or test result during the logic test and also select output of the RAM 101 during the RAM test and operation of user in view of providing outputs to the side of the comparing circuit 140 and logic circuit LC2. Accordingly, the flip-flop FF4 can be used in common during the logic test and RAM test.

Moreover, the selectors SEL1, SEL2, SEL3, SEL4 are controlled with the selection control signal selmi from a mode control circuit 160, while the selectors SEL21, SEL22 are controlled with the selection control signal selmo. The mode control circuit 160 can be constituted to generate the selection control signals selmi, selmo by providing a register for setting a code to instruct RAM test mode, or logic test mode, or ordinary operation mode and also providing a decoder.

FIG. 2 illustrates, as an example of the logic circuit, a logic circuit LC1 for generating write data of the RAM 101 and a logic circuit LC2 for processing read data from the RAM 101. The logic circuits LC1, LC2 are respectively provided with combining logic circuits LA1, LA2, LA3, and LA4, flip-flops FF21, FF22, FF23, and FF24 which are provided among each combining logic circuits LA1, LA2, LA3, and LA4 and form a shift register during the test, and selectors SEL31, SEL32, SEL33, and SEL34 for switching the signal paths. A scan-in path of test pattern and a scan-out path of test result can be formed by switching the selectors SEL31, SEL32, SEL33, and SEL34 during the test.

In FIG. 2, according to the convenience of a size of drawing and content of explanation, the path is so illustrated that the signal transmitted from the logic circuit LC1 via the scan-path LSP2 for logic is supplied to the selector SEL14. However, it is also possible to constitute the circuit in which the signal transferred via the LSP2 is supplied to the selector SEL13 and is then latched with the FF3. Accordingly, the flip-flops FF3 and FF4 may be used in common for both logic test and RAM test. This is also true to the other flip-flops FF1, FF2, . . . .

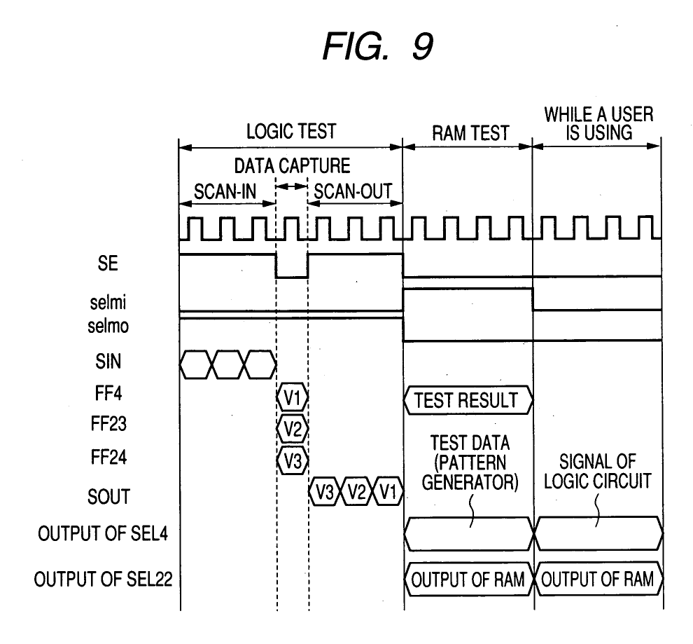

Relation between the logic test and memory test is illustrated in FIG. 9. Namely, during the logic test, the scan-in SIN of test pattern from the logic BIST 170 is executed first. In this timing, the selection control signal selmi is set to “L”, while the selmo to “H” and the test data is fetched by the flop-flops FF21, FF22, and FF4 through the scan-path LSP1 within the logic circuit LC1 and the scan-path LSP2 between the logic circuit and boundary latch. This test data is inputted to the combining circuits LA2, LA3.

Next, data capture is executed. In this timing, the scan-enable signal SE in FIG. 2 becomes “0” and the signal (output V1 of LA2) selected in the selector SEL4 is inputted to the flip-flop FF4. Moreover, a result (V2) of the flip-flop FF4 selected by the selector SEL22 is inputted to the flip-flop FF23 and the signal (output V3 of LA3) selected by the selector SEL34 is inputted to the flip-flop FF24.

In the scan-out timing, result of each Flip-flop FF4, FF23, and FF24 is outputted as SOUT through the scan-path LSP4 between the path and logic circuit LC2 and the scan-path LSP2 in the logic LC2 within the boundary latch.

During the RAM test, the selection control signal selmi is set to “H” and selmo to “L”. The selector SEL4 is controlled to select the signal from the pattern generator 120 while the selector SEL22 is controlled to select an output of the RAM 101. Therefore, the test result of the RAM test is stored to the flip-flop FF4. During the ordinary operation different from the test operation, both selection control signals selmi and selmo are set to “L”. In this timing, the selector SEL4 is controlled to the side to select an output of the logic circuit LC1, while an output of the selector SEL22 becomes an output of the RAM.

The BISR circuit 150 comprises a column address determining circuit 151 for determining column address corresponding to fail bits on the basis of a comparison result of the comparing circuit 140, a multi-fail circuit 152 for determining whether a plurality of fails are included or not based on the read data of RAM scanned out from the boundary latch 131 and the signal from the BIST control circuit 110, a sequential encoder 153 for generating the encoded relief information based on the signal from the BIST control circuit 110, and a shift data control circuit 154 for generating the enable signal to the multi-fail circuit 152 and sequential encoder 153 based on a value of the counter provided in the BIST control circuit 110.

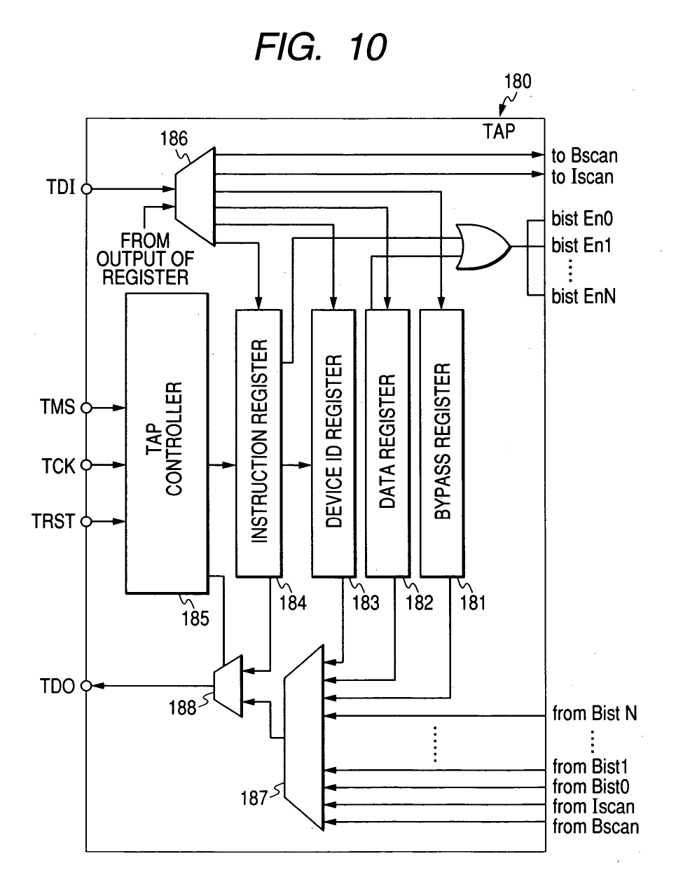

The relief information generated by the sequential encoder 153 is sent to a redundant circuit, when such redundant circuit is provided in the RAM for replacing the memory column including fail bits to the reserve memory column, or is once sent to an interface circuit 180 called TAP (Test Access Port) when such redundant circuit is not provided, and thereafter outputted to the external side of chip via the TAP. The TAP is the interface circuit which is specified by the specifications for boundary scan-test which has been determined with an organization called JTAG (Joint Test Action Group). The TAP will be explained later in detail with reference to FIG. 10.

The comparing circuit 140 comprises exclusive OR gates G1, G2, . . . as the comparator for inputting the read data of RAM supplied via selectors SEL21, SEL22, . . . and the expected value data supplied from the pattern generating circuit 120, an OR gate G20 for outputting the logical sum obtained of outputs of the exclusive OR gates G1, G2, . . . , a selector SEL20 for selecting the output of the OR gate G20 or the output of the flip-flop FF4, a flip-flop FF20 for latching the signal selected with the selector SEL20, an OR gate G21 for obtaining the logical sum of the outputs of the FF20 and OR gate G20 and then supplying this logical sum to the selector SEL20, and OR gates G31, G32, etc., . . . for obtaining the logical sum of the outputs of the exclusive OR gates G1, G2, . . . and the outputs of the flip-flops FF3, FF4, . . . and then returning this logical sum to the FF3, FF4, . . . via the selectors SEL3, SEL4, . . . .

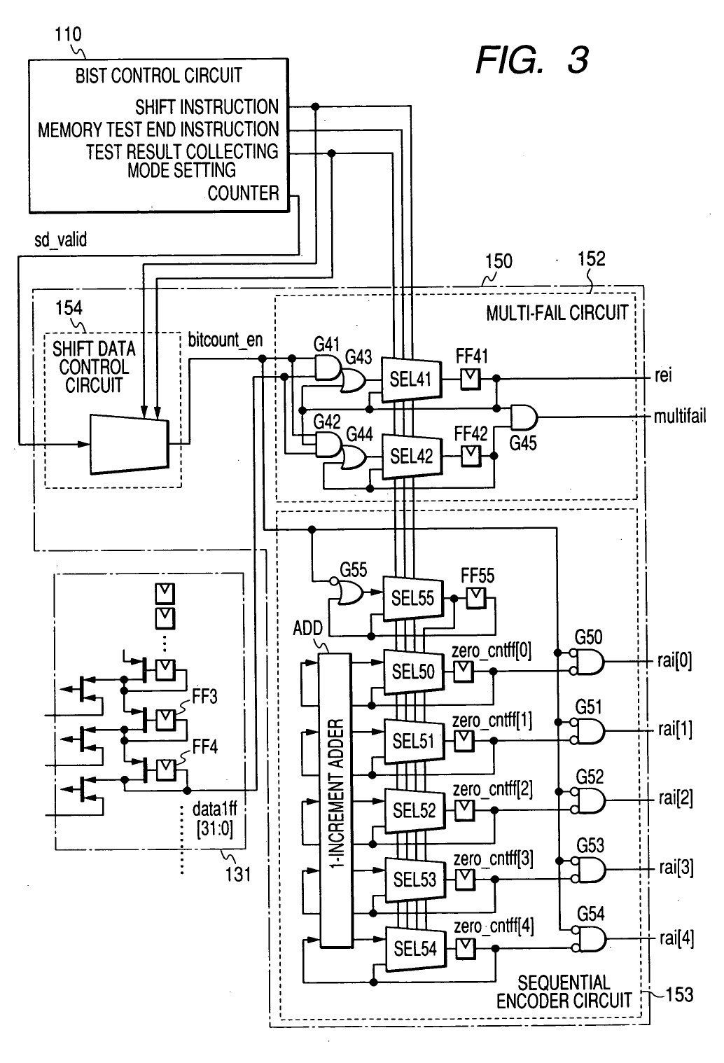

FIG. 3 illustrates more detail structures of the multi-fail circuit 152 and sequential encoder 153, except for the column address determining circuit 151, of the BISR circuit 150. In this embodiment, a structure of the BISR circuit 150 corresponding to the RAM is illustrated, wherein the IO bits are formed of 32 bits. The shift data control circuit 154 is formed of a decoder to which a value “sd_valid” of the counter 111 in the BIST control circuit 110 is inputted. This shift data control circuit 154 asserts, while the counter value is 32 bits for the multi-fail circuit 152, the bit count enable signal “bitcount_en” and negates, when the counter value exceeds 32 bits, the bit count enable signal “bitcount_en”.

The counter value “sd_valid” is also supplied to the BISR circuit 150 corresponding to the other RAM. In the case where the number of IO bits of such RAM is, for example, 16 bits, the shift data control circuit 154 in the corresponding BISR circuit 150 is constituted to assert, until the counter value “sd_valid” reaches the maximum value of 16 bits, the bit count enable signal “bitcount_en” to the high level and negate, when the counter value exceeds 16 bits, the bit count enable signal “bitcount_en” to the low level.

The multi-fail circuit 152 comprises AND gates G41, G42 for allowing fetch of the determination result being stored in the flip-flops FF3, FF4, . . . of the boundary latch 131 only during the period in which the bit count enable signal “bitcount_en” from the shift data control circuit 154 is in the high level, OR gates G43, G44 for obtaining the logical sum of the output signals of the gates G41, G42 and feedback signal, selectors SEL41, SEL42 for selecting the output signals of the gates G43, G44 or the feedback signal, flip-flops FF41, FF42 for latching the signal selected by the selectors SEL41, SEL42, and an AND gate G45 for obtaining the logical product of the output signals of the flip-flops FF41, FF42. This multi-fail circuit 152 outputs the state of the flip-flop FF41 as the fail signal “rei” indicating existence or non-existence of fail bits and also outputs an output of the AND gate G45 as the multi-fail signal “multi_fail” indicating existence or non-existence of a plurality of fail bits.

The sequential encoder 153 comprises an OR gate G55 for obtaining the logical sum of the inverted signal of bit count enable signal “bitcount_en” from the shift data control circuit 154 and the feedback signal, a selector SEL55 for selecting the output signal of the gate G55 or the feedback signal, a flip-flop FF55 for latching the signal selected with the selector SEL55, an adder ADD having the increment function, selectors SEL50 to SEL 54 for selecting the output signal of the adder ADD or the feedback signal, flip-flops FF50 to FF54 for latching the signal selected by the selectors SEL50 to SEL54, and AND gates G50 to G54, etc., for obtaining the logical product of the inverted signals of the output signals of FF50 to FF54 and the bit count enable signal “bitcount_en” from the shift data control circuit 154, in order to execute the operations of the counter circuit as a whole. This sequential encoder 153 is controlled to operate like a counter circuit as a whole and therefore inverts the counter value with the AND gates G50 to G54 and outputs the inverted signals as the relief information (corresponding to the information indicating locations of fail bits) “rai[0]” to “rai[4]”.

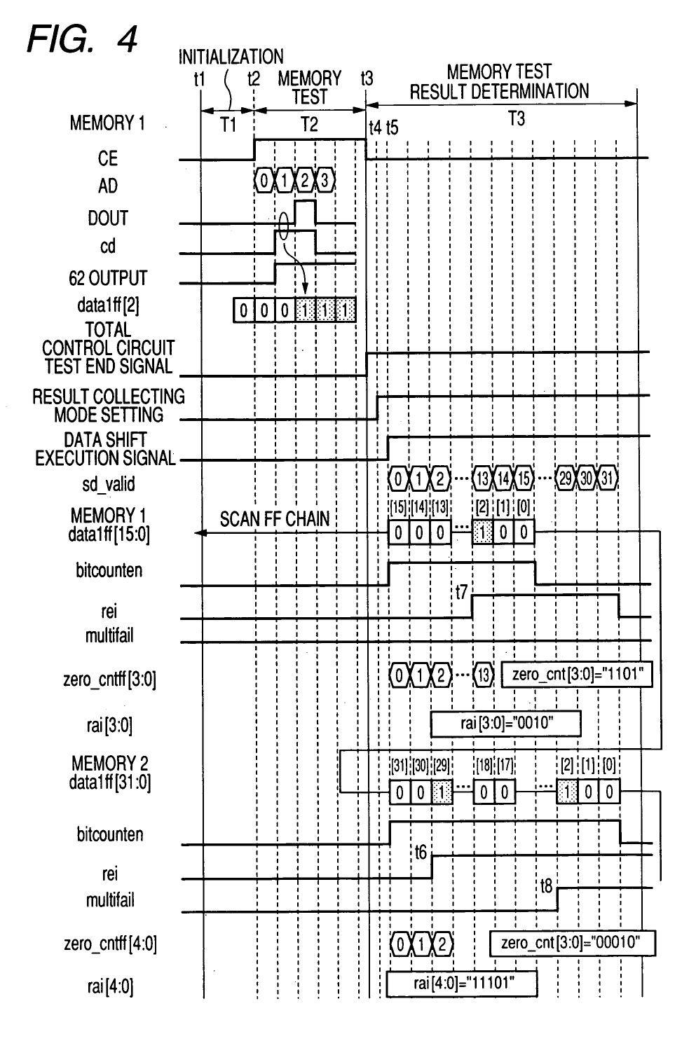

Here, the relief information generating operation in the BISR circuit of FIG. 3 will be explained with reference to the timing chart of FIG. 4.

When test of the RAM starts, the BIST circuit is initialized first (period T1 in FIG. 4) with the BIST control circuit 110, such as reset or the like of the flip-flops in the boundary latch 131, multi-fail circuit 152 and sequential encoder 153. Thereafter, the pattern generating circuit 120 is driven to conduct the test of the RAMs 101 to 103 with the pattern data generated (period T2 in FIG. 4). In this test of RAM, the data is written into the RAMs 101 to 103 in accordance with the pattern data generated by the pattern generating circuit 120 and then comparison with the expected value is conducted during read operation of data. Thereafter, the comparison result is then stored into the flip-flops FF3, FF4, . . . in the boundary latch 131.

In FIG. 4, only DOUT [2] is described as an output of the RAM at the reading part, but it is also true for the outputs from the other DOUT terminals. When a read operation of the RAM starts, the CE signal of RAM becomes “1” and the address signal AD changes to 0, 1, 2, . . . . When the output DOUT[2] of RAM is outputted as 0, 0, 1, . . . , a result of comparison with the expected signal cd from the pattern generator of FIG. 2 becomes an output of the circuit G2 in the comparing circuit 140. When the address signal AD is address 1, since an output DOUT[2] of RAM is “0” and the expected value signal cd is “1”, an output of the circuit G2 becomes “1” as the fail result of the comparison result. The logical sum of the output of the circuit G2 and a result of boundary latch 131 is fed back to the boundary latch 131 via the OR circuit G32 in order to update the result of boundary latch (FF3 of FIG. 2, datalff [2] of FIG. 4). Therefore, when the address signal AD is “2”, output result is identical to the expected value result. However, since the result of boundary latch is already “1”, result of boundary latch is maintained thereafter as “1”.

Next, when operation of the pattern generating circuit 120 stops, the test end signal is issued from the BIST control circuit 110 (timing t3 in FIG. 4). Next, when the data shift execution signal is validated (timing t5) when the test result collecting mode is set (timing t4), the selectors SEL13, SEL14 . . . within the boundary latches 131 to 133 are set to operate the flip-flops FF3, FF4, . . . as the shift register. The counter in the BIST control circuit 110 is driven and thereby the counter value “sd_valid” is updated. Moreover, the test result stored in the flip-flops FF3, FF4, . . . within the boundary latches 131 to 133 is shifted through the scan-path (period T3 in FIG. 4).

During this period, the bit count enable signal “bitcount_en” is asserted to the valid level within the BISR circuit and thereby the multi-fail circuit 152 and sequential encoder 153 are activated. In the multi-fail circuit 152, an output “rei” is changed to high level (timings t6 and t7) when “1” indicating mismatching between the read dada and the expected value is inputted as the comparison result data sent from the flip-flops FF3, FF4, . . . in the boundary latches 131 to 133. Meanwhile, the sequential encoder 153 conducts the counting operation in synchronization with shift operation of the flip-flops FF3, FF4, . . . and the counting up operation is stopped when the output “rei” is changed to high level (timings t6, t7).

FIG. 4 illustrates the timings in which the 3rd bit from the least significant bit is mismatched with the expected value in the RAM 101 and the 3rd bit from the most significant bit and the 3rd bit from the least significant bit are mismatched with the expected value under the condition that the number of IO bits of RAM 101 is “16” and the number of IO bits of RAM 102 is “32”. In the BISR circuit in the side of RAM 101, the count value of the sequential encoder 153 is “1101” in the timing that mismatching of the 3rd bit data from the least significant bit is detected and the output “rei” is changed to high level and this value is converted to complement with the AND gates G50 to G54 and is then outputted as “rai[0]” to “rai[3]”=“0010”.

On the other hand, in the BISR circuit in the side of RAM 102, the count value of the sequential encoder 153 is “00010” in the timing t6 when mismatching of the data of 3rd bit from the most significant bit is detected and “rei” is changed to high level, and this count value is converted to the complement with the AND gates G50 to G54 and is then outputted as “rai[0]” to “rai[4]”=“11101”. Moreover, in the case of FIG. 4, since two bit errors are detected in the BISR circuit in the side of RAM 102, the signal “multi_fail” from the multi-fail circuit 152 indicating that error of two or more bits exists is changed to high level in the timing t8 when the error of 2nd bit is detected.

As explained above, the test time can be saved and thereby manufacturing cost can also be reduced by simultaneously conducting the test to a plurality of memories such as RAM 101 and RAM 102 of different memory capacities and by generating the relief information.

The memory in which only one reserve memory is prepared as will be explained later is illustrated as an example. However, it is possible to output the relief information by modifying the structure of the multi-fail circuit 152 into the adequate structure from that of this embodiment even when a plurality of reserve memories are prepared or even when the doubled output bits of the memory are provided for only one port like the dual-port.

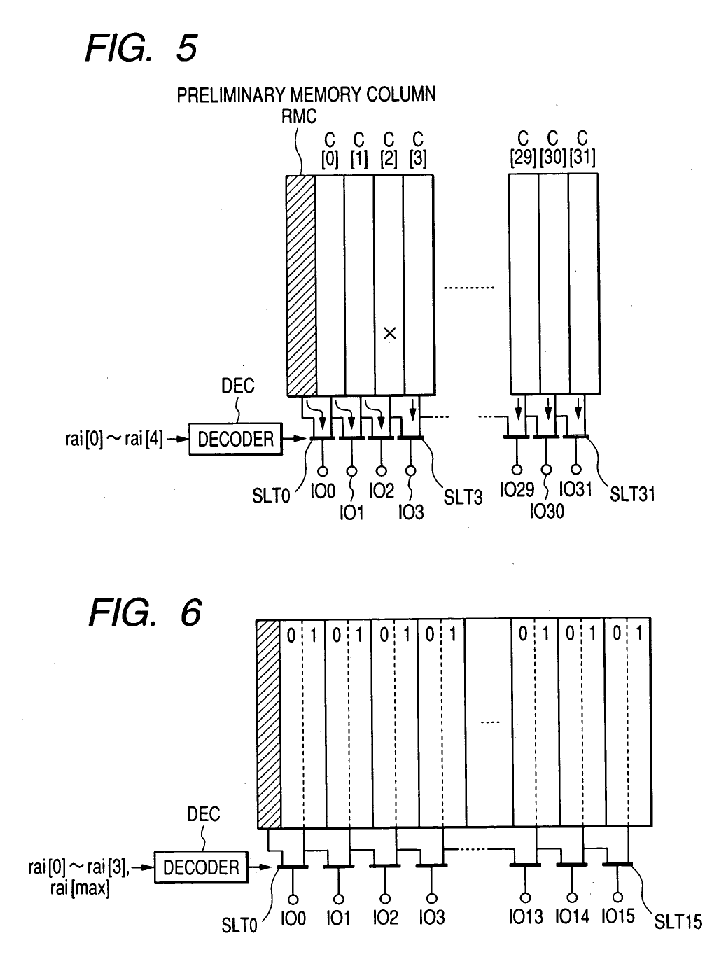

FIG. 5 illustrates a schematic structure of the relief circuit provided to the RAM. In the schematic structure of the relief circuit illustrated in FIG. 5, one reserve memory column RMC is prepared for 32 memory columns C[0] to C[31]. SLT0 to SLT31 are selectors for outputting any one of read data of adjacent two memory columns to the corresponding data input/output terminals IO0 to IO31 and these selectors SLT0 to SLT31 are controlled to output the read data by skipping the memory columns including fail bits, by an output of the decoder DEC for decoding the relief information pieces “rai[0]” to “rai[4]” outputted from the sequential encoder 153.

In more concrete, when it can be assumed, for example, that fail bit is included in the 3rd memory column C[2], the selectors SLT0 to SLT31 are controlled so that the data of the reserve memory column RMC and memory columns C[0] to C[1] are outputted to the data input/output terminals IO0 to IO2 by the selectors SLT0 to SLT3, and the data of the memory columns C[3] to C[31] are outputted to the data input/output terminals 103 to 1031 by the selectors SLT4 to SLT31. Although not illustrated in the figure, a selector is also provided. This selector is controlled, in the same manner for writing the data to each memory column C[0] to C[31] to supply the data inputted to the data input/output terminals IO3 to IO31 by skipping the memory column including fail bits.

FIG. 7 illustrates a concrete structure example of the column address determining circuit 151 in the BISR circuit 150. The column address determining circuit 151 determines, when the RAM is formed as the IO column, the memory column including fail bit in one IO column. In this embodiment, one IO column is formed of two memory columns in the structure of the column address determining circuit 151.

As illustrated in FIG. 7, the column address determining circuit 151 of this embodiment comprises a set of selectors SEL61, SEL62, a set of flip-flops FF61, FF62, an exclusive OR gate G61 for obtaining exclusive local sum of the output of FF61 and output of FF62, a NOR gate G62 for generating the signal “rei” indicating requirement/non-requirement of relief by obtaining the logical sum of the output of the gate G61 and the output “multi_fail” of the multi-fail circuit 152, and an encoder ENC for generating the most significant bit “rai[max]” of the relief address by encoding the output of the FF61 and the output of the FF62.

The selectors SEL61, SEL62 respectively input the most significant bit “adrff[colmax]” of the column address from the pattern generating cicuit 110 and an output “rf” of the flip-flop FF20 for holding the comparison result of the comparing circuit 140. When “adrff [colmax]” is “0” and “rf” is “1”, “1” is set to the flip-flop FF61 and the output “raicoloff” is set to “1”, and when “addrff[colmax]” is “1” and “rf” is “1”, “1” is set tot the flip-flop FF62 and the output “raicollff” is set to “1”.

The signal “raicol0ff” indicates, when this signal is “0”, that there is no fail in the column where “adrff [colmax]” is 0 and also indicates, when this signal is “1”, that fail exists in this column. The signal “raicollff” indicates, when this signal is “0”, there is no fail in the column where “adrff[colmax]” is “1” and indicates, when this signal is “1”, that fail exists in this column.

An output “col_jud” of the exclusive OR gate G61 indicates, when this output is “0”, that relief of column is necessary and also indicates, when this output is “1”, that relief of column is unnecessary. On the other hand, an output “rai [max]” of the encoder ENC indicates whether any column of the IO should be saved and therefore indicates, when this output is “0”, relief of the column where the most significant bit of the column address is “0” is necessary and indicates, when this output is “1”, relief of the column where the most significant bit of the column is “1” is unnecessary.

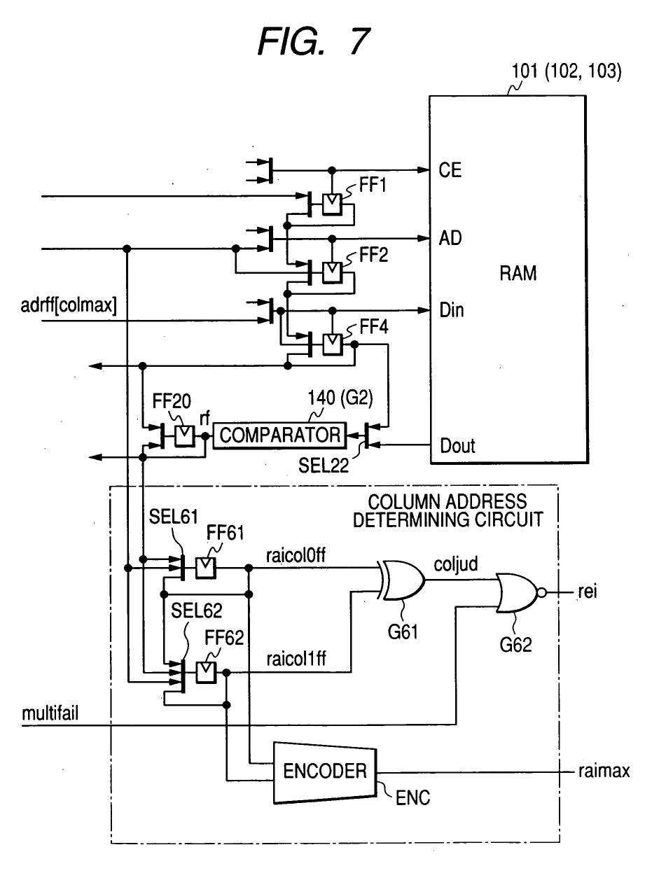

FIG. 6 illustrates a schematic structure of the relief circuit provided in the RAM of the IO column structure. In the schematic structure of FIG. 6, an example of the relief circuit is illustrated. Namely, 16 IO columns IOC[0] to IOC[15] are respectively formed of two memory columns and one reserve memory column RMC is prepared for 16 IO columns IOC[0] to IOC[15]. In FIG. 6, “0” and “1” indicated at the upper part of each memory column are most significant bits “adrff [colmax]” of the column address.

Moreover, the selectors SLT0 to SLT15 are provided to output any one of read data of the adjacent two IO columns to the corresponding data input/output terminals IO0 to IO15 and these selectors SLT0 to SLT15 are controlled to output the read data by skipping the memory column including fail bits with the relief information “rai[0]” to “rai[3]” outputted from the sequential encoder 153 and the output of the decoder DEC for decoding the output “rai [max]” (“rai [4]” in this embodiment) from the encoder ENC of the column address determining circuit 151.

In the embodiment described above of the present invention, the logic integrated circuit comprises a logic circuit having the predetermined logic functions, a memory circuit (built-in RAM101 or the like) which can read or write the data, and test circuit (110, 120) for testing whether fail bit is included in the memory circuit or not and also provides, between the logic circuit and memory circuit, a boundary latch circuit (131 or the like) constituted with a plurality of flip-flop circuits which is capable of latching the signals and forming a shift register. Moreover, since this logic integrated circuit is further provided with a fail relief information generating circuit (150) to store the test result into the boundary latch circuit during execution of the test using a test circuit and to generate the fail relief information for relieving fail of the memory circuit on the basis of the test result stored, the information for relieving the fail bit is generated and then outputted to the external side of a chip or the memory circuit can also be relieved within the chip in parallel with the test of the built-in memory circuit. In addition, since the test result of the test circuit is stored to the boundary latch circuit and the fail relief information generating circuit generates the fail relief information to relieve fail of the memory circuit on the basis of the test result stored, the information for relieving fail bit of the memory circuit can be generated while increase in the scale of circuit is restrained.

Moreover, since the memory circuit is provided with a reserve memory group and a fail relief circuit for replacing the internal main memory group with a reserve memory group and the information generated by a fail relief information generating circuit is supplied to the fail relief circuit for replacement of memory groups, relief of fail bit can be executed in parallel with the test of the built-in memory circuit.

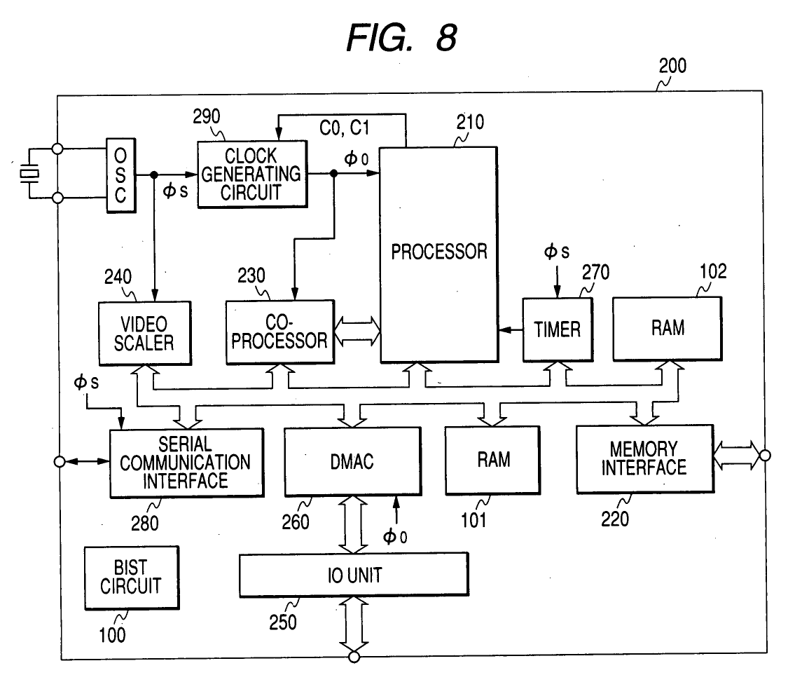

Next, an example of structure of a system LSI will be explained as an example of the well applicable logic integrated circuit comprising a built-in BIST circuit of the embodiment described above. In FIG. 8, the circuit including the BIST control circuit 110, test pattern generating circuit 120 and bridge circuit illustrated in FIG. 1 and FIG. 2 are illustrated as a block 100.

The system LSI 200 in this embodiment is mounted, for example, into a portable type electronic apparatus to execute total control operations and data processing of dynamic images or the like. The system LSI of this embodiment is provided with a processor 210 for executing programs, a memory interface 220 for executing data access control to the main memory such as externally connected SDRAM (Synchronous DRAM) or the like, a co-processor 230 or executing arithmetic operation process required for encoding and decoding of the dynamic image data, and a video scaler 240 for executing data processes or the like required for compression and expansion of dynamic images and encoding and decoding thereof.

Moreover, the system LSI 200 is also provided with an IO unit 250 for exchanging data with an externally connected input/output device, a DMA (Direct Memory Access) controller 260 for executing direct data transfer between peripheral modules and main memory or the like without using the processor 210, a timer circuit 270 for generating timer interrupt signal to the processor 210 and clocking the present time, and a serial communication interface 280 for executing serial communication to and from an external device.

The system LSI is further provided with a clock generating circuit 290 for generating clock signal φ0 required for internal operations of the LSI 200, and RAM 101, RAM 102, and RAM 103 (not illustrated) which are used as the work regions of the processor 210 and co-processor 230 and are also used for temporarily storing external data and the data generated in the system LSI 120.

FIG. 10 illustrates an embodied example of the interface circuit 180 using the TAP illustrated in FIG. 2.

The TAP is the interface and control circuit for the scan test and BIST circuit specified with the IEEE1149.1 standards. This TAP is provided with a bypass register 181 used for shifting test data sent from an input port to an output port, a data register 182 used for transferring the particular signal to the circuit, and a device ID register 183 for setting the specific manufacture identifying number of a chip. Moreover, the TAP is also provided with a controller 185 or the like for totally controlling the instruction register 184 and TAP circuit used for selecting the data register and controlling the internal test method.

The data register 182 is an optional register. Moreover, as the instructions to be set to the instruction register 184, four essential instructions and three optional instructions are prepared. To the controller 185, the test mode select signal TMS, test clock signal TCK, and reset signal TRST are inputted from the exclusive three external terminals, and the control signal for the registers 181 to 184 and selector circuits 186 to 188 is formed on the basis of the signals explained above.

In addition, since the TAP is also provided with an input terminal of the test data TDI and an output terminal of the test result data TDO, the inputted test data TDI is supplied to each register 181 to 184 or to the internal scan paths Iscan, Bscan via the selector circuit 186. Moreover, contents of registers 181 to 184 and scan out data from the internal circuit are outputted to the external side of chip via the selector circuits 187, 188. Moreover, the signal for the internal BIST circuit is formed in accordance with contents of the data register 182 and instruction register 184 and is then supplied to the TAP, and the signal indicating the test result outputted from the BIST circuit can be outputted to the external side of the chip via the selector circuits 187, 188.

In FIG. 10, the internal scan path “Iscan” forms the scan path (LSP) by coupling the flip-flops forming an internal logic circuit in the shape of chain and means the internal logic circuit and the test path for diagnosis by giving the test data from the external tester or the like. Moreover, the internal scan path “Bscan” forms the scan path (SP) by coupling the flip-flops provided within the boundary latch provided at the boundary of the logic circuit and RAM in the shape of chain and means the internal logic circuit and test path for diagnosis of RAM by giving the test data from the external tester or the like. For the LSI in which the test is executed by the BIST and the test result is outputted to the external side of chip via the BIST, use of the test function using the scan paths “Iscan” and “Bscan” is not required.

In the LSI including the TAP having the constitution explained above as the interface for the test function, it is possible to realize a semiconductor integrated circuit device which requires only several pins (4 to 5 pins) of the test terminal. Accordingly, the chip size can be reduced by reducing the number of pins of the LSI. Moreover, since the TAP of the constitution illustrated in FIG. 10 is standardized and renewal of design thereof is not required, and the design of the other LSI can also be used, the period required for development can also be reduced.

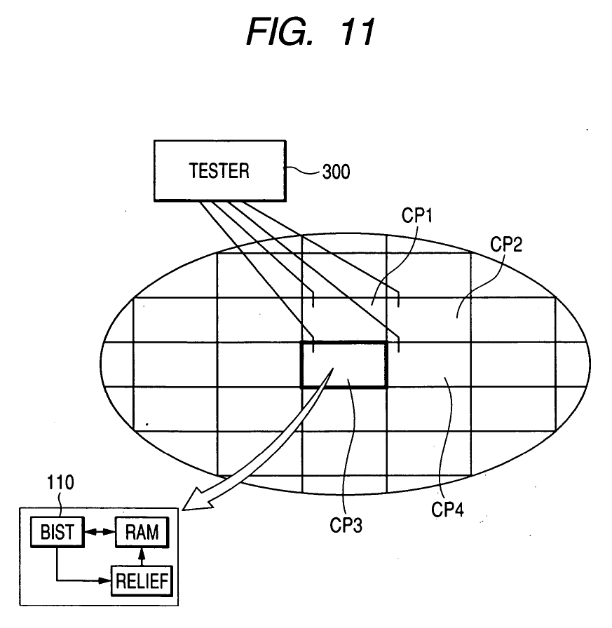

In addition, since the number of test terminals is small and the fail relief circuit and repair circuit of RAM are built in, a probe is put to the power supply terminal and the test terminal of a plurality of chips CP1, CP2, CP3, CP4, . . . using a tester 300 as illustrated in FIG. 11 in order to test and relieve the RAM within the chip in the wafer state and also to test the logic circuit. It can be done easily that the test operation is executed in parallel to simultaneous supply of the power supply voltage to a plurality of chips and test results can also be collected in parallel from a plurality of chips.

Moreover, since the self-repair circuit and relief circuit or the like for relieving the RAM on the basis of the BIST circuit 110 which generates the test pattern of RAM and the fail relief information obtained by generating the fail relief information from the test result are also built in, the test can be executed only by a logic tester without use of a memory tester even when the semiconductor integrated circuit comprises the built-in RAM.

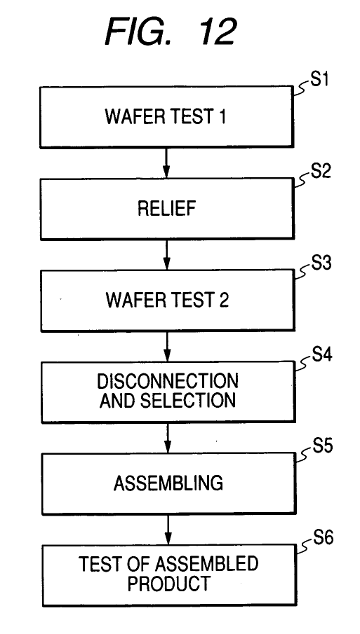

FIG. 12 is a flowchart illustrating the testing process and assembling process of the logic integrated circuit simultaneously mounting the RAM and logic circuits of the present invention.

As illustrated in FIG. 12, the test is conducted three times in total, including twice in the wafer state and once after the assembling. In the case of the first wafer test (step S1), the logic circuit and RAM are tested by operating the built-in BIST circuit explained in the embodiment and the RAM is relieved on the basis of the test result (step S2). When the logic gate or the like for relief is also provided to the logic circuit, this logic circuit is also relieved. Thereafter, the second test (step S3) is conducted and selection for good device and no-good device is conducted (step S4) based on the result of test S3 after each chip is extracted from the wafer. After the good device is assembled into a package (step S5), the product test is conducted (step S6). This product test can also be executed using the built-in BIST circuit.

The step S1 and the step S2 are clearly separated, when the RAM is relieved using a laser fuse or the like, for disconnecting a fuse with a device which disconnect the fuse on the basis of the collected information after the relief information is collected. Meanwhile, when the RAM is relieved with a CMOS fuse or the like, relief can be realized by storing the relief information to a non-volatile memory or the like and then controlling the switch of CMOS based on the stored information. Accordingly, the step S1 and the step S2 can be done simultaneously, testing time can be saved, the device for disconnecting the fuse is no longer required, the steps S1 and S2 can be executed with the same device, and the cost required for test can also be saved.

The invention which has been proposed by the present inventors has been described concretely on the basis of the embodiment thereof but the present invention is not limited to the embodiment described above and allows various changes or modifications without departure from the scope of the invention. For example, in above embodiment, the number of IO bits of the built-in RAM is set to 32 bits and 16 bits, but the present invention can also be adapted to the cases where the number of IO bits is selected to 8 bits, 64 bits or the bits not expressed by the raised power of 2. Moreover, the present invention can be adapted to the case where a plurality of reserve memories are used or a dual-port RAM is used. In addition, in the embodiment described above, a TAP circuit has been mounted on the same chip together with RAM and BIST circuit. However, the present invention can also be adapted to the case where the TAP circuit is mounted to the other chip or the TAP is not provided.

Moreover, in the embodiment described above, as a redundant circuit for replacing the memory column including fail with the reserve memory column, the slide system redundant circuit has been used, in which a selector for selective connection with one data line of the adjacent memory column is provided between the memory array and data input/output terminal in view of selecting the memory columns by skipping the memory column including fail. However, the present invention can also be adapted to the case where a redundant circuit system is used, in which an address setting circuit is included for storing fail address using fuses which can be programmed with laser.

In above description, the present invention by the present inventors has been adapted to the system LSI simultaneously mounting the RAM and the logic circuits such as CPU which has been considered as the application field as the background of the present invention. However, the present invention can also be adapted to an LSI comprising a built-in read/write memory circuit other than the RAM, for example, a built-in rewritable non-volatile memory circuit.

What is claimed is:

1. A semiconductor integrated circuit comprising:
a logic circuit having logic functions;
a read/write memory circuit;
a test circuit for testing whether fail bit is included in said memory circuit or not;
a boundary latch circuit formed of a plurality of flip-flop circuits which are capable of latching signals between said logic circuit and said memory circuit, and the boundary latch circuit forming a shift register; and
a fail relief information generating circuit,
wherein during execution of a test, said fail relief information generating circuit generates fail relief information for relieving fail of said memory circuit on the basis of test result while said test circuit is collecting said test result from said boundary latch circuit.

2. The semiconductor integrated circuit according to claim 1,
wherein said memory circuit includes a main memory group, a reserve memory group, and a fail relief circuit for replacing a part of said main memory group including fail with said reserve memory group, and
wherein said main memory group including fail is replaced by supplying the information generated by said fail relief information generating circuit to said fail relief circuit.

3. The semiconductor integrated circuit according to claim 2, wherein said reserve memory group is formed of memory columns allocated along the column direction within said memory circuit.

4. The semiconductor integrated circuit according to claim 1,
wherein said test circuit is provided with a test pattern generating circuit for generating a test pattern for testing said memory circuit, and
wherein a test result of said memory circuit is stored into said boundary latch circuit with the test pattern generated by said test pattern generating circuit.

5. A semiconductor integrated circuit comprising:
a logic circuit having logic functions;
a plurality of read/write memory circuits in which the number of read bits is different;
a test circuit for testing whether fail bit is included to said memory circuit or not;
a plurality of boundary latch circuits, formed of a plurality of flip-flop circuits, being capable of latching signals between said logic circuit and a plurality of memory circuits and also forming a shift register; and
a plurality of fail relief information generating circuits,
wherein during execution of a test, a plurality of said fail relief information generating circuits generate fail relief information for relieving fail of corresponding said memory circuit on the basis of test result while said test circuit is collecting said test result from said boundary latch circuit.

6. The semiconductor integrated circuit according to claim 5, wherein a plurality of said boundary latch circuits of a plurality of said memory circuits are coupled to be able to form a shift scan-path.

7. The semiconductor integrated circuit according to claim 5,
wherein a plurality of said memory circuits respectively include a main memory group, a reserve memory group, and a fail relief circuit for replacing a part of said main memory group including fail with said reserve memory group, and
wherein said main memory group including fail is replaced by supplying information generated by said fail relief information generating circuit to said fail relief circuit.

8. The semiconductor integrated circuit according to claim 7, wherein said reserve memory group is formed of memory columns allocated along the column direction within said memory circuit.

9. The semiconductor integrated circuit according to claim 5,
wherein said test circuit includes a common test pattern generating circuit for generating a test pattern for testing a plurality of said memory circuits, and
wherein the test result of said memory circuit is stored to said boundary latch circuit with the test pattern generated by said test pattern generating circuit.

10. The semiconductor integrated circuit according to claim 8, wherein said fail relief circuit is provided with a plurality of selectors for selectively connecting anyone of data lines of adjacent memory columns provided between a memory array and data input/output terminal within said memory circuit with corresponding data input/output terminal among said data input/output terminals, and a plurality of said selectors are controlled to select the data line by skipping the memory column including fail.

11. A semiconductor integrated circuit comprising:
a logic circuit including logic function;
a read/write memory circuit;
a first scan path for supplying test data to said logic circuit and extracting test result; and
a second scan path for supplying test data to said memory circuit and extracting test result,
wherein a plurality of flip-flop circuits are respectively provided in the course of said first scan path and said second scan path, the flip-flop circuit on said first scan path for storing the test result of said logic circuit and the flip-flop circuit on said second scan path for storing the test result of said memory circuit are used in common.

12. The semiconductor integrated circuit according to claim 11,
wherein selector circuits for switching a path of signal are respectively provided in the course of said first scan path and said second scan path, and
wherein said selector circuits switch the path, during ordinary operation different from test operation, so that a significant signal does not pass through the flip-flop circuit storing said test result.

13. The semiconductor integrated circuit according to claim 11, wherein a fail relief information generating circuit is provided in order to generate fail relief information for relieving a fail of said memory circuit on the basis of the test result of said memory circuit.

14. The semiconductor integrated circuit according to claim 13, wherein operation for collecting the test result of said memory circuit and operation of said fail relief information generating circuit for generating the fail relief information on the basis of said test result are executed so as to overlap for a certain period.

15. The semiconductor integrated circuit according to claim 11, wherein the a test pattern generating circuit is provided for generating a test pattern to test said memory circuit.

16. The semiconductor integrated circuit according to claim 13, comprising:
a plurality of memory circuits;
a fail relief information generating circuits provided respectively corresponding to a plurality of said memory circuits; and
a relief circuit for relieving fail within the corresponding memory circuit on the basis of fail relief information generated by said fail relief information generating circuit,
wherein fail relief information generating operation of the fail relief information generating circuit corresponding to each of a plurality of said memory circuits and the fail relief operation in the relief circuit are executed so as to overlap for a certain period in a plurality of said memory circuits.

17. The semiconductor integrated circuit according to claim 16, wherein a common test pattern generating circuit is provided to generate the test pattern for testing a plurality of said memory circuits.

18. The semiconductor integrated circuit according to claim 11, wherein a logic test circuit is provided for supplying test pattern for testing said logic circuit to said logic circuit via said first scan path and for collecting the test result via said first scan path.

19. The semiconductor integrated circuit according to claim 11, wherein the test pattern inputted from an outside is supplied to said logic circuit via said first scan path and the test result is outputted to the outside via said first scan path.

20. A method for manufacturing semiconductor integrated circuit comprising: a logic circuit having logic function; a read/write memory; a first scan path for supplying test data to said logic circuit and extracting test result; and a second scan path for supplying test data to said memory circuit and extracting test result,
said method comprising:
a first step for forming, on a wafer, a plurality of semiconductor integrated circuits in which a plurality of flip-flop circuits are respectively provided in the course of said first scan path and said second scan path and the flip-flop circuit on said first scan path to store test result of said logic circuit and the flip-flop circuit on said second scan path to store test result of said memory circuit are used in common;
a testing step for testing the circuits within said semiconductor integrated circuits after said first step;
a second step for selecting a semiconductor integrated circuit chip on the wafer on the basis of the test result after said testing step; and
a third step for assembling the selected semiconductor integrated circuit chip into a package after said second process.

21. The method for manufacturing semiconductor integrated circuit according to claim 20, wherein tests are executed in parallel respectively using said first and said second scan paths of a plurality of semiconductor integrated circuits on the wafer, and respective test results are collected in parallel from a plurality of said semiconductor integrated circuits in said testing step.

22. A method for manufacturing semiconductor integrated circuit including: a logic circuit having logic function; a read/write memory, a first scan path for supplying test data to said logic circuit and extracting test result; and a second scan path for supplying test data to said memory circuit and extracting test result,
said method comprising:
a first step for forming, on a wafer, a plurality of semiconductor integrated circuits in which a plurality of flip-flop circuits are respectively provided in the course of said first scan path and said second scan path and the flip-flop circuit on said first scan path to store the test result of said logic circuit and the flip-flop circuit on said second scan path to store the test result of said memory circuit are used in common;
a first testing step for testing circuits in said semiconductor integrated circuits after said first step;
a relieving step for relieving a fail of memory circuit within semiconductor integrated circuit chip on the basis of test result after said first testing step;
a second testing step for testing circuits in said semiconductor integrated circuits after said relieving step;
a selecting step for selecting a semiconductor integrated circuit chip on the wafer on the basis of the test result after said second testing step;
an assembling step for assembling the selected semiconductor integrated circuit chip after said selecting step; and
a third testing step for testing an assembled product after said assembling step.

23. The method for manufacturing semiconductor integrated circuit according to claim 22, wherein a plurality of said semiconductor integrated circuits on the wafer are respectively provided with a pattern generating circuit for generating a test pattern and a test circuit including a comparing circuit for comparing the test result with the expected value, and respectively execute test operation by said test circuit in said first testing step, second testing step, and third testing step.

24. A method for manufacturing semiconductor integrated circuit including: a plurality of memory circuits; a fail relief information generating circuits respectively provided corresponding to a plurality of said memory circuits; and a relief circuit for relieving a fail in corresponding memory circuit on the basis of fail relief information generated by said fail relief information generating circuit,
said method comprising:
a first step for forming, on a wafer, a plurality of semiconductor integrated circuits in which fail relief information generating operation in the fail relief information generating circuit corresponding respectively to a plurality of said memory circuits and fail relief operation in the relief circuit are executed so as to overlap for a certain period respectively in a plurality of said memory circuits;
a testing step for testing circuits in said semiconductor integrated circuits after said first step;
a selecting step for selecting semiconductor integrated circuit chip on the wafer on the basis of test result after said testing step;
and an assembling step for assembling the selected semiconductor integrated circuit chip into a package after said selecting step,
wherein the test operation of the memory circuit and the fail relief information generating operation are executed so as to overlap for a certain period respectively in a plurality of said semiconductor integrated circuits on the wafer in said testing step, and the test operation of the memory circuit and the fail relief information generating operation are executed so as to also overlap for a certain period in a plurality of said semiconductor integrated circuits on the wafer.

25. The method for manufacturing semiconductor integrated circuit according to claim 24, wherein tests are executed in parallel in a plurality of said semiconductor integrated circuits on the wafer by simultaneously supplying a power supply voltage to a plurality of said semiconductor integrated circuits on the wafer using a tester in said testing step, and respective test results are collected in parallel from a plurality of said semiconductor integrated circuits using said tester.

26. The method for manufacturing semiconductor integrated circuit according to claim 25, wherein said tester is a logic tester.
